(19) United States
(12) Patent Application Publication
(10) Pub. No.: US 2004/0196082 A1
(43) Pub. Date: Oct. 7, 2004

(54) Circuit arrangement

(75) Inventors: Christian Pacha, Muenchen (DE); Roland Thewes, Grobenzell (DE); Klaus von Amim, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 10/723,309

(22) Filed: Nov. 26, 2003

(30) Foreign Application Priority Data
Nov. 28, 2002 (DE) 102 55 636.9

(51) Int. Cl. H03K 3/037

(52) U.S. Cl. 327/215

(57) ABSTRACT

A circuit arrangement comprising a flip-flop, a first power switch transistor, and a plurality of switching transistors. The flip-flop has a plurality of storage transistors with a threshold voltage of a first value. The first power switch transistor has a threshold voltage of a second value, wherein an application of a predetermined electrical potential to its gate terminal brings the circuit arrangement to an operating state such that if at least one supply voltage is switched off, electric charge carriers contained in the circuit arrangement are prevented from flowing away from the circuit arrangement. The plurality of switching transistors, which have a threshold voltage of a third value, are provided between the flip-flop and the first power switch transistor, for coupling a flip-flop input signal into the flip-flop. The magnitude of the first and/or the second value is greater than the magnitude of the third value.

### CROSS-REFERENCE TO RELATED APPLICATION

This application is based on German application no. 10255636.9 filed on Nov. 28, 2003, and is incorporated herein by reference in its entirety.

### FIELD OF THE INVENTION

The invention relates to a circuit arrangement.

### BACKGROUND OF THE INVENTION

An energy-saving mode of operation is essential in mobile devices such as a mobile telephone or a PDA device (“personal digital assistant”). For this reason, it is desirable in a device of this type that it can be used in an energy-saving mode.

If such a device contains field-effect transistors, then transistors having a low value of the threshold voltage are advantageous since they enable operation with a high processing speed and with a low value of the supply voltage. However, a transistor having a low threshold voltage has a high subthreshold current, which leads to an accelerated discharge of the battery particularly in integrated circuits for mobile devices such as mobile telephones or PDAs. A transistor having a low threshold voltage is susceptible to the occurrence of leakage currents. Such leakage currents are, by way of example, a subthreshold current or a gate leakage current when simultaneously using a thin gate oxide (e.g., <2 nm).

In order to master this problem, in an energy-saving operating mode (“standby” or “power-down” mode), it is possible to reduce leakage current components of a CMOS circuit by providing power switches realized by means of transistors having a high threshold voltage and a large thickness of the gate-insulating layer. If such a transistor having a high threshold voltage is turned off in an energy-saving operating mode, then it prevents leakage currents from flowing away and consequently the battery from discharging. The leakage current components include, in particular, the subthreshold current and the gate leakage current of transistors having a low threshold voltage and a small thickness of the gate-insulating layer. By means of turned-off power switches, the electrical coupling between transistors having a low threshold voltage and a ground potential V_{SS} (in the case of n-MOS power switches) or a supply voltage V_{DDL} (in the case of p-MOS power switches) is interrupted in the standby mode in the circuit. The power switch transistor has a high value of the threshold voltage and a large thickness of the gate-insulating layer, so that the leakage currents are in this case preferably three to four decades lower than in the case of the transistors having a low threshold voltage and a thin gate-insulating layer. In order, in the active operating state of the circuit, to ensure a sufficiently good electrical coupling between transistors of the circuit and an assigned electrical potential (ground potential, supply voltage), the power switch transistor can be operated with a higher supply voltage (e.g., V_{DDH}=1.2V to 1.5V in the case of a 100 nm CMOS technology). A circuit technology of this type is known by the term “multi-V_{DD}/V_{T} circuit technology”, since a plurality of different supply voltages and transistors having different values of the threshold voltage are provided, see M. Hamada, Y. Ootaguro, T. Kuroda, “Utilizing Surplus Timing for Power Reduction”, Proc. of the IEEE Custom Integrated Circuits Conference 2001. Depending on switching activities and the requirement made of the speed, a suitable voltage swing may thus be chosen for a specific application. For a logic circuit, it is necessary to determine for this merely the number and dimensioning of the power switch transistors.

T. Inukai et al., “Boosted gate MOS (BGMOS): device/circuit cooperation scheme to achieve leakage-free giga-scale integration”, Proceedings of the Custom Integrated Circuits Conference, 2000, pp. 409-412, discloses the so-called “boosted gate CMOS technology”. This technology combats the problem occurring in conventional CMOS circuits that, with the implementation of transistors having a low threshold voltage and a small thickness of the gate-insulating layer, leakage currents arise in a standby or power-down mode, and lead to an accelerated discharge of the battery particularly in an integrated circuit for mobile devices such as mobile telephones or PDAs. Therefore, in a separate, energy-saving operating mode, the leakage current components of the CMOS circuit are protected against an excessively large leakage current by means of power switches being turned off.

The principle of the “boosted gate CMOS technology” is illustrated in FIG. 1.

FIG. 1 shows a circuit arrangement 100 comprising a CMOS circuit 101 and a power switch circuit 102. The CMOS circuit 101 contains a multiplicity of first field-effect transistors 103, which are realized as transistors having a low threshold voltage and a small thickness of the gate-insulating layer. The power switch circuit 102 is formed from a second field-effect transistor 104 having a high threshold voltage and a large thickness of the gate-insulating layer. The CMOS circuit 101 is operated using a supply voltage 105 VDD and a ground potential 106 GNDV. A standby voltage 107 is present at the gate terminal of the second field-effect transistor 104 in a standby mode, whereas an active state voltage 108 V_{boost} is present at the gate terminal of the second field-effect transistor 104 in an active state mode. In the standby mode, the second field-effect transistor 104 having the high value of the threshold voltage turns off sufficiently reliably, thereby avoiding a flowing away of electric charge carriers from the CMOS circuit 101.

A circuit may contain flip-flop stores which store a state in registers or which are used in a data path for synchronization. These states, in which storage information is coded, are also intended to be preserved in a standby mode if the storage content is not stored in an external store. The latter option is ruled out in particular when standby mode and active mode alternate rapidly with respect to time and the intention is to avoid an additional energy consumption for saving or rewriting the storage content. One difficulty in the implementation of flip-flops in multi-V_{DD}/V_{T}-CMOS logic consists in the permanent storage of a datum that has previously been written to the flip-flop in the case of power switches having been switched off. In contrast to logic circuits, the internal storage nodes of the flip-flop are intended always to have an unambiguous voltage level (V_{DD} or V_{SS}), so that the state of the flip-flop is preserved.

The prior art discloses using additional circuit components for a storage flip-flop in order to buffer-store data stored in the flip-flop during a standby mode. However, additional circuit components bring about an increased requirement for area and power.

S. Shigematsu et al., “A 1-V high-speed MTCMOS circuit scheme for power-down application circuits”, IEEE Journal of Solid-State Circuits, Vol. 32, No 6, June 1997, pp. 861-869, discloses using an additional storage flip-flop constructed from transistors having a sufficiently high threshold voltage. Such an arrangement needs a high area requirement and additional control lines in order to write or write back items of information to the storage nodes of the flip-flop.

P. R. van der Meer, A. van Staveren, A. H. M. Roermund, “Ultra low Standby Currents for deep sub micron VLSI CMOS Circuits: Smart Series Switch”, ISCAS 2000—IEEE International Symposium on Circuits and Systems, May 28 to 31, 2000, Geneva, Switzerland and P. R. van der Meer, A. van Staveren, “Effectivity of Standby-Energy Reduction Techniques for Deep-Sub-Micron CMOS”, ISCAS 2001. Proc. of the 2001 IEEE International Symposium on Circuits and Systems (ISCAS), Vol. 4, pp. 594-597, disclose the use of a so-called “triple series switch”, in which an n-MOS and p-MOS power switch are used and supplemented by each case two parallel n-MOS and p-MOS transistors having a sufficiently high threshold voltage. Depending on the electrical potential on the storage nodes, an electrically conductive path to a supply voltage is produced via the additional transistors in the standby mode. The power switches are to be driven with a voltage above the supply voltage V_{DD} or below the lower reference voltage V_{SS}. The additional transistors are arranged in the critical path of the flip-flop, that is to say in the path along which data signals are coupled into the flip-flop, and thus represent an additional load on account of which the propagation time through the flip-flop is increased undesirably.

S. F. Huang et al., “High performance 50 nm CMOS devices for microprocessor and embedded processor core applications”, Technical Digest. International Electron Devices Meeting, 2001, pp. 11.1.1-11.1.4 discloses a sub-100 nanometre CMOS technology.

J. Montanaro et al, “A 160 MHz, 32b, 0.5 W CMOS RISC Microprocessor”, IEEE Journal of Solid State Circuits, Vol. 31, No. 11, November 1996, pp. 1703 1714, and U.S. Pat. No. 4,910,713 disclose flip-flops and pulse generators.

U.S. Pat. No. 6,232,801 discloses a flip-flop using inverters and switching transistors.

T. Hiramoto, “Optimum Device Parameters and Scalability of Variable Threshold Voltage Complementary MOS (VTCMOS)”, J. Appl. Phys. Vol. 40 (2001) Part 1, No. 413, 30 Apr. 2001, pp. 2854-2858, describes how the threshold voltage can be set in the case of a field-effect transistor.

R. Zyuban and D. Meltzer, “Clocking Strategies and Scannable Latches for Low Power Applications”, Proc. of the International Symposium on Low Power Electronics and Design (ISLPED) 2001, Huntington Beach, Calif., USA, pp. 346-351, discloses a scan arrangement as test circuit for a flip-flop.

DE 196 15 413 A1 discloses an integrated semiconductor circuit with a logic circuit connected between a virtual voltage supply line and a virtual ground line, a p-MOS transistor being connected between the virtual voltage supply line and an actual voltage supply line, and an n-MOS transistor being connected between the virtual ground line and an actual ground line.

DE 197 13 495 A1 discloses a method and a circuit arrangement for testing integrated solid-state circuits.

EP 1,193,871 A2 discloses a latch and a flip-flop.

EP 1,170,865 A2 discloses an integrated semiconductor circuit, a logic operation circuit and a flip-flop.

US 2002/0047737 A1 discloses a flip-flop which receives a clock signal, delays the clock signal by a predetermined time interval and detects the delay time interval from the clock signal.

JP 2002-250753 A discloses a scan test circuit, a method for testing the same, and a method for initialising a flip-flop.

### SUMMARY OF THE INVENTION

The invention is based on the problem of providing a circuit arrangement having a flip-flop which can be operated in a standby mode, signal times for passing through the circuit arrangement being intended to be sufficiently short.

The problem is solved by means of a circuit arrangement having the features in accordance with the independent patent claim.

The circuit arrangement according to the invention contains a flip-flop having a plurality of storage transistors having a threshold voltage of a first value. Furthermore, the circuit arrangement has a power switch transistor having a threshold voltage of a second value, which transistor is set up in such a way that, by means of the application of a predeterminable electrical potential to its gate terminal, the circuit arrangement can be brought to an operating state in which electric charge carriers contained in the circuit arrangement, in the event of at least one supply voltage being switched off, are protected against flowing away from the circuit arrangement. Furthermore, the circuit arrangement according to the invention contains a plurality of switching transistors having a threshold voltage of a third value between the flip-flop and the power switch transistor, for coupling a flip-flop input signal into the flip-flop. The first and/or the second value of the threshold voltage are/is greater than the third value.

A basic idea of the invention is to be seen in the fact that the circuit arrangement according to the invention realizes storage transistors of the flip-flop and/or the power switch transistor with a higher value of the threshold voltage than the switching transistors for coupling an electrical signal into the flip-flop. On account of the sufficiently large value of the threshold voltage of the storage transistors of the flip-flop, a flowing away of electric charge carriers from the flip-flop, and thus a loss of the storage information, are avoided even in a standby mode in which at least one supply voltage of the circuit arrangement is switched off. The use of a power switch transistor having a sufficiently high value of the threshold voltage makes it possible to avoid an undesirable flowing away of electric charge carriers from nodes of the circuit arrangement in a standby mode. The switching transistors are clearly located between power switch transistor and the storage transistors and thus in the propagation path of data signals which are coupled into the storage flip-flop. The low value of the threshold voltage of the switching transistors means that the latter have a high driver capability, thereby keeping down the delay or attenuation of a data signal which is coupled into the flip-flop by means of the switching transistors.

An item of storage information for a standby mode can be reliably stored in the circuit arrangement by means of as little as one additional component, the power switch transistor. This ensures that the area requirement of the circuit arrangement remains tenably low. Furthermore, a high signal speed is made possible in the circuit arrangement, since the propagation path of the signals is free of transistors having a high value of the threshold voltage. Consequently, the advantages of the transistors having a high threshold voltage (low leakage current) and transistors having a low threshold voltage (low signal delay and attenuation) are clearly combined in an advantageous manner. An energy-saving storage possibility in a power-down mode is thereby created, particularly for mobile devices such as a PDA.

In other words, what is provided according to the invention is a circuit arrangement having a flip-flop which can be operated in an energy-saving standby mode. The flip-flop may be implemented for example in static CMOS technology and may be based on a sub-100 nm technology in which transistors having different threshold voltages and thicknesses of the gate-insulating layer are provided (multi-V_{T} CMOS technology). The circuit arrangement with flip-flop is suitable in particular for a low-loss circuit with low supply voltages (for example V_{DDL}=0.5V to 0.8V) in which the active power loss is reduced on account of the lower voltage swing in comparison with circuits having nominal voltages. Circuits of this type are generally formed from transistors having the lowest value of the threshold voltage which is available in the process.

The invention enables the implementation of a flip-flop with permanent storage capability in the standby mode with a very low outlay. Said outlay essentially consists in the provision of the additional power switch transistor.

In other words, what is provided is a circuit arrangement for a flip-flop which can be operated in an energy-saving standby mode. The flip-flop can be implemented in static CMOS technology and is preferably based on a sub-100 nm CMOS technology in which transistors having different values of the threshold voltage and the thickness of the gate-insulating layer are provided. The flip-flop is suitable particularly for low-power-loss circuits with low supply voltages, for example in the range of V_{DDL}=0.5V-0.8V.

The implementation of a flip-flop with permanent storage capability in a standby mode is therefore made possible. Clearly, all or at least a portion of the components of the flip-flop which are relevant to the switching speed are switched off by means of a power switch and the leakage currents of these components (e.g., transistors in the data path) are eliminated. Only a storage unit that is preferably formed from low-leakage-current transistors remains coupled to a supply voltage V_{DDL} and to a ground potential V_{SS} in the standby mode.

Preferred developments of the invention emerge from the dependent claims.

The flip-flop may have two inverters formed from the storage transistors. The inverter subcircuits are preferably connected up to one another with feedback and formed from two p-MOS and two n-MOS transistors.

A common power switch transistor may be provided for the flip-flop of the circuit arrangement and at least one additional flip-flop. In other words, the power switch transistor according to the invention may be formed jointly for a plurality of flip-flops, thereby reducing the area requirement of the circuit arrangement. Typically, a common power switch transistor is provided for in each case a few hundred flip-flops.

The thickness of the gate-insulating layer of the storage transistors and/or of the power switch transistor is preferably greater than the thickness of the gate-insulating layer of the switching transistors. The fact that storage transistors and power switch transistors are formed with a sufficiently high threshold voltage and a sufficiently large thickness of the gate-insulating layer and the fact that the switching transistors are configured with a low threshold voltage and a small thickness of the gate-insulating layer intensify the functionality of power switch and storage transistors as low-leakage-current transistors and the functionality of the switching transistors as strong driver components.

The channel width of the storage transistors and/or of the power switch transistor is preferably less than the channel width of the switching transistors.

The switching transistors may be connected up in such a way that a portion of the terminals or even all the terminals of the switching transistors have a defined electrical potential in an operating state of the circuit arrangement in which at least one supply voltage of the circuit arrangement is switched off. The situation in which (e.g., in a standby mode) terminals of the switching transistors are at an undefined “floating” electrical potential is avoided by means of this configuration. This enables a reliable retention of the storage content of the flip-flops in a standby mode.

The circuit arrangement may have at least one second power switch transistor, which is coupled to at least a portion of the switching transistors in such a way that, in an operating state of the circuit arrangement in which the at least one supply voltage of the circuit arrangement is switched off, the gate terminals of the switching transistors coupled to the at least one second power switch have a defined electrical potential. The error robustness of the circuit arrangement or the retention time of the information stored in the flip-flop in a standby mode can be considerably improved by means of the at least one second power switch transistor.

Furthermore, provision may be made of at least one third power switch transistor, which is coupled to at least a portion of the switching transistors in such a way that, in an operating state of the circuit arrangement in which the at least one supply voltage of the circuit arrangement is switched off, a source/drain terminal of the switching transistors coupled to the at least one third power switch transistor have a defined electrical potential. The at least one third power switch transistor is preferably a p-MOS field-effect transistor. By means of the introduction of the at least one third power switch transistor, a defined electrical potential is provided to the associated nodes of the circuit arrangement in the standby mode, thereby increasing the electrical stability of the circuit arrangement.

The circuit arrangement may furthermore have a pulse generator circuit for generating a flip-flop input signal from an input signal and a clock signal, which pulse generator circuit is coupled to the power switch transistor and to the switching transistors. By means of the pulse generator circuit, a flip-flop input signal can be generated as input signal for the flip-flop from a clock signal and an input signal (data signal).

The pulse generator circuit may have a plurality of pulse generator transistors having a fourth value of the threshold voltage, the first and/or the second value being greater than the fourth value in terms of magnitude.

Since the pulse generator transistors are arranged in the critical propagation path between input signal and flip-flop, it is advantageous to provide the transistors contained therein with a low threshold voltage. What are particularly advantageous are a configuration of the pulse generator transistors and the switching transistors with a low value of the threshold voltage and a small thickness of the gate-insulating layer and a configuration of the power switch transistor and the storage transistors as transistors with a high threshold voltage and a large thickness of the gate-insulating layer.

It should be noted that the values of the threshold voltage of the different storage transistors may be of different magnitudes. Furthermore, the values of the threshold voltage of the switching transistors may be of different magnitudes among one another. Analogous statements apply to the thickness of the gate-insulating layers of the transistors and/or to the channel widths thereof.

The pulse generator circuit may have a logic subcircuit for generating at least one flip-flop input signal from at least one input signal in accordance with a predeterminable logic operation. To put it another way, a logic module (or a plurality of logic modules) which logically manipulates the input signal or logically combines a plurality of input signals with one another in accordance with a predeterminable Boolean logic operation may be integrated in the pulse generator circuit with the functionality of generation of a flip-flop input signal from an input signal and a clock signal. The logic subcircuit may be set up in such a way that the logic operation is an inverter operation, an AND operation, an OR operation, a NAND operation, a NOR operation, an exclusive-OR operation or an exclusive-NOR operation. Any desired logic operation or the complement thereof can be implemented in the logic subcircuit.

The logic subcircuit may have a plurality of logic transistors having a fifth value of the threshold voltage, the first and/or the second value being greater than the fifth value in terms of magnitude. Since the logic transistors of the logic subcircuit of the pulse generator circuit are located in the signal propagation path between input signal and flip-flop, it is advantageous to configure these transistors with a low value of the threshold voltage or a small thickness of the gate-insulating layer in order that the signals are not excessively delayed or attenuated.

The circuit arrangement may furthermore have a control unit for controlling supply voltages which can be applied to terminals of at least a portion of the transistors of the circuit arrangement. The control unit is set up in such a way that, in an energy-saving operating state, it can switch off all the supply voltages with the exception of supply voltages of the flip-flop (i.e., of the storage transistors). The control unit can thus be set up for initiating the standby mode. A corresponding control signal may be effected for example externally by means of an input by a user in a device containing a circuit arrangement according to the invention. Such a device may be a mobile telephone or a PDA, for example. After reception of a corresponding control signal, the control unit can switch off all the supply voltages with the exception of those for supplying the flip-flop. As a result, a substantial part of the energy supply of the circuit arrangement is switched off and an energy-saving operation is made possible. Only an upper and a lower electrical reference potential of the flip-flop circuit should be provided to the circuit arrangement even in the standby mode, in order to ensure reliable retention of the information stored in the flip-flop.

The at least one flip-flop of the circuit arrangement may be coupled to a test circuit which is set up for testing the functionality of the flip-flop. Such a test circuit or a scan circuit makes it possible to check the functionality of the flip-flop, for example by a signal being written to the flip-flop and subsequently being read out. It can thus be checked whether an input signal stored in a flip-flop is reliably stored in the latter. The functionality of such a test circuit can be integrated, according to the invention, in the circuit arrangement.

The test circuit of the circuit arrangement may have an input component, set up for programming a test input signal into the flip-flop, and may have an output component, set up for reading out a test output signal from the flip-flop.

The test circuit may have a plurality of test transistors having a sixth value of the threshold voltage, the sixth value being greater than the third value and/or the fourth value and/or the fifth value in terms of magnitude. Since testing is a non-time-critical functionality in comparison with the active operation of the circuit arrangement, the test transistors preferably have small dimensioning and have a high threshold voltage or a high thickness of the gate-insulating layer.

The test transistors may have a gate-insulating layer having a greater thickness than the thickness of the gate-insulating layer of the switching transistors and/or of the pulse generator transistors and/or of the logic transistors. Consequently, the test transistors preferably have a sufficiently thick gate-insulating layer. Consequently, transistors having different threshold voltages and thicknesses of the gate-insulating layer are combined with one another according to the invention. Time-critical functions such as the charge reversal of loads are preferably realized using transistors having a low threshold voltage and a thin gate-insulating layer and are switched off in the standby mode. Non-time-critical functions such as the storage function of the flip-flop generate minimal leakage current since they are formed from transistors with a high threshold voltage and a thicker gate-insulating layer. The additional outlay is low since only different masks are necessary for the different transistor types in the layout.

With regard to the circuitry realization, additional control signals are unnecessary for putting the flip-flop into the active state again after the end of the standby mode (so-called write-back signal, see S. Shigematsu et al.). The invention thus makes it possible to avoid both an increased area requirement and the increase in the propagation time on account of additional circuit components.

Additional configurations of the circuit arrangement according to the invention are described below, in which, in a standby mode, storage information stored in the flip-flop is protected particularly reliably from being lost on account of undesirable flowing away of electric charge carriers through the switching transistors that are preferably provided with a low threshold voltage. In the case of unfavourable dimensioning and process variations, it is not always precluded that a flowing away of electric charge carriers containing an item of storage information at nodes of the flip-flop is avoided with sufficient reliability by means of switching transistors that are opened in the standby mode. An additional improvement of the output stage of the circuit arrangement is achieved by means of the configurations of the circuit arrangement according to the invention described below.

In accordance with this configuration, the circuit arrangement may have one or more protection transistors having a threshold voltage of a seventh value between the flip-flop and the switching transistors, which protection transistors are connected up for selectively coupling or decoupling flip-flop and switching transistors, the seventh value being greater than the third value in terms of magnitude.

The protection transistors may have a gate-insulating layer having a greater thickness than the thickness of the gate-insulating layer of the switching transistors and/or of the pulse generator transistors and/or of the logic transistors. Consequently, the protection transistors preferably have a sufficiently thick gate-insulating layer.

In particular, the circuit arrangement may be set up in such a way that, in a first operating state of the circuit arrangement, in which at least one supply voltage of the circuit arrangement is switched off, by means of electrical control signals being prescribed to the protection transistors, the latter electrically decouple flip-flop and switching transistor from one another. In a second operating state of the circuit arrangement, in which the circuit arrangement is supplied with a supply voltage, by means of electrical control signals being prescribed to the protection transistors, flip-flop and switching transistors are electrically coupled to one another by means of the protection transistors.

In accordance with one preferred configuration, the protection transistors may have at least one transistor pair of transistors of different conduction types which are connected in parallel with one another, which at least one transistor pair is connected by its source/drain terminals between flip-flop and switching transistors.

These configurations increase the robustness of the circuit arrangement according to the invention and reduce the static power loss of sense-amplifier-based flip-flops with storage functionality in the standby mode. Consequently, the situation in which the internal storage content of a storage circuit that is active in the standby mode is overwritten in an undesirable manner by means of floating electrical potentials and process variations is avoided sufficiently reliably. An additionally improved output stage of the circuit arrangement is clearly provided.

The configurations described are based on a selective decoupling—i.e., a decoupling that can optionally be prescribed by means of corresponding control signals—of the internal storage circuit of the flip-flop from the switching transistors optimised to a high signal transfer speed (SET/RESET driving of the output stage) by means of the protection transistors which are connected up according to the invention and may be formed for example by means of two transmission gates.

This configuration is compatible with the scan path realization improved according to the invention and with the integrated logic stage that is preferably contained in the circuit arrangement.

Clearly, the protection transistors are provided as transistors having a higher value of the threshold voltage than the switching transistors, it being possible to apply to the protection transistors in a standby mode a voltage signal such that the protection transistors prevent an undesired flowing away of electric charge carriers that code an item of storage information from the flip-flop into the switching transistors. This good blocking effect of the protection transistors in their off state is based on their high value of the threshold voltage. In the normal operation of the circuit arrangement, the protection transistors can be supplied with a control voltage such that they are at sufficiently low impedance in order to realize a signal transfer between flip-flop and switching transistors at sufficiently low impedance, rapidly and without greatly increasing the load.

A parallel circuit comprising two mutually complementary transistors (n-MOS, p-MOS) is particularly advantageous. Instead of such a transmission gate, an individual n-MOS or p-MOS transistor, for example, may also be used for decoupling or coupling between the feedback inverters of the flip-flop. However, the use of a transmission gate has the advantage that, unlike with the use of individual n-MOS or p-MOS transistors, in active operation, approximately the full electrical potential (V_{DD} in the case of n-MOS, V_{SS} in the case of p-MOS) can be forwarded to the feedback inverters. The use of a transmission gate instead of an individual n-MOS or p-MOS transistor avoids the result obtained from simulations where a considerable increase in the CLK-Q (clock, storage node) delay time by up to 50% takes place since the complete logic levels are only achieved through the regeneration in the slower feedback inverters.

### BRIEF DESCRIPTION OF THE DRAWINGS

Exemplary embodiments of the invention are illustrated in the figures and are explained in more detail below.

FIG. 1 shows a circuit arrangement in accordance with the prior art;

FIG. 2 shows a diagram showing different transistor types;

FIG. 3 shows a circuit arrangement in accordance with a first exemplary embodiment of the invention;

FIG. 4 shows a circuit arrangement in accordance with a second exemplary embodiment of the invention;

FIG. 5 shows a circuit arrangement in accordance with a third exemplary embodiment of the invention;

FIG. 6 shows a circuit arrangement in accordance with a fourth exemplary embodiment of the invention;

FIG. 7 shows a circuit arrangement in accordance with a fifth exemplary embodiment of the invention;

FIG. 8 shows a circuit arrangement in accordance with a sixth exemplary embodiment of the invention;

FIG. 9 shows a circuit arrangement in accordance with a seventh exemplary embodiment of the invention;

FIG. 10 shows another illustration of the circuit arrangement in accordance with the seventh exemplary embodiment of the invention; and

FIG. 11 shows timing diagrams for illustrating the operation of the circuit arrangement in accordance with the seventh exemplary embodiment of the invention.

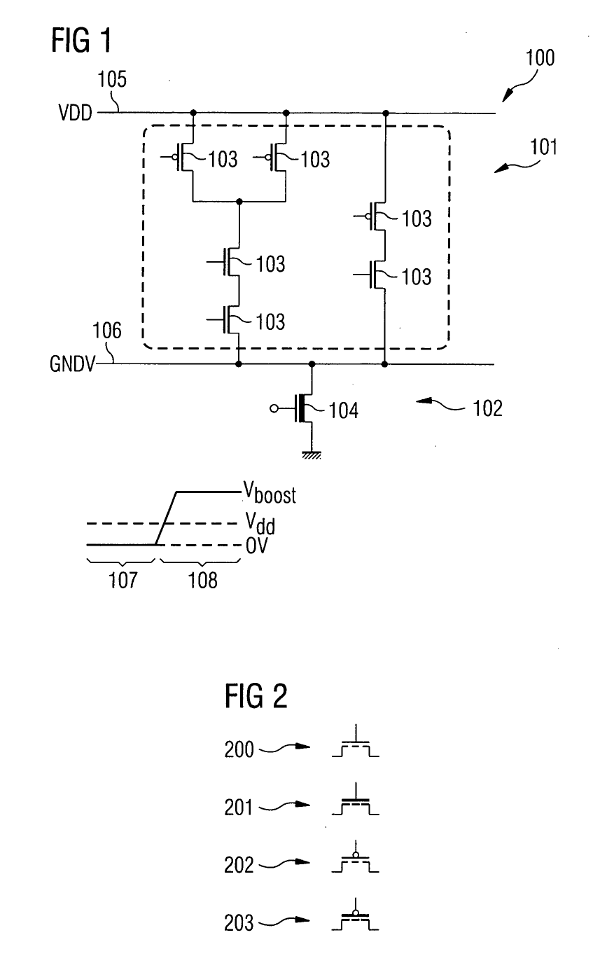

### DETAILED DESCRIPTION OF THE PREFERRED MODE OF THE INVENTION

Identical or similar components in different figures are provided with identical reference numerals.

The illustrations in the figures are diagrammatic and not to scale.

A symbol notation for different field-effect transistors used in the figure is agreed below with reference to FIG. 2.

A low threshold voltage n-MOS field-effect transistor 200 has a threshold voltage value which is lower than the threshold voltage value of a high threshold voltage n-MOS field-effect transistor 201. What is more, the high threshold voltage n-MOS field-effect transistor 201 has a gate-insulating layer having a high thickness. Furthermore, a low threshold voltage p-MOS field-effect transistor 202 has a threshold voltage value which is lower than the threshold voltage value of a high threshold voltage p-MOS field-effect transistor 203. What is more, the high threshold voltage p-MOS field-effect transistor 203 has a gate-insulating layer having a high thickness. It should be noted that, in a circuit arrangement 300 to 800 in which a plurality of transistor types 200 to 203 are integrated, not all the transistors of a respective type 200 to 203 need have an identical threshold voltage value.

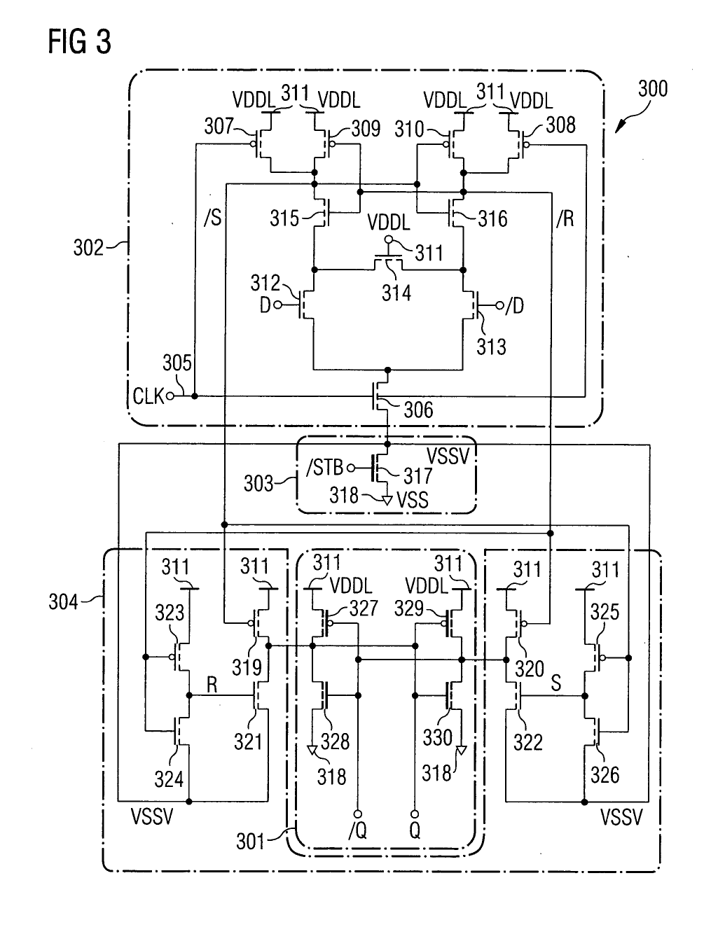

A circuit arrangement 300 in accordance with the first exemplary embodiment of the invention is described below with reference to FIG. 3.

The circuit arrangement 300 has a flip-flop subcircuit 301, a pulse generator subcircuit 302, a power switch subcircuit 303 and a coupling-in subcircuit 304.

The pulse generator subcircuit 302 contains a clock input 305, to which a clock signal CLK can be applied. The clock input 305 is coupled to a gate terminal of a first n-MOS pulse generator circuit 306 and of a first and of a second p-MOS pulse generator transistor 307, 308. Furthermore, a first source/drain terminal of the first p-MOS pulse generator transistor 307 is coupled to a first source/drain terminal of a third p-MOS pulse generator transistor 309. A first source/drain terminal of the second p-MOS pulse generator transistor 308 is coupled to a first source/drain terminal of a fourth p-MOS pulse generator transistor 310. Furthermore, the respective second source/drain terminals of the transistors 307 to 310 are at the electrical potential of a supply voltage 311 VDDL. A first source/drain terminal of the first n-MOS pulse generator transistor 306 is coupled to respective first source/drain terminals of a second and of a third n-MOS pulse generator transistor 312, 313. A data signal D can be applied to the gate terminal of the second n-MOS pulse generator transistor 312, and a complementary data signal /D with respect to the data signal D can be applied to the gate terminal of the third n-MOS pulse generator transistor 313. The second source/drain terminals of the transistors 312, 313 are coupled to a respective source/drain terminal of a fourth n-MOS pulse generator transistor 314, to the gate terminal of which the supply voltage 311 VDDL can be applied. The second source/drain terminal of the second n-MOS pulse generator transistor 312 is coupled to a first source/drain terminal of a fifth n-MOS pulse generator transistor 315. The second source/drain terminal of the fourth n-MOS pulse generator transistor 313 is coupled to a first source/drain terminal of a fifth n-MOS pulse generator transistor 316. The gate terminal of transistor 315 is coupled to the gate terminal of transistor 309, and the gate terminal of transistor 316 is coupled to the gate terminal of transistor 310. The second source/drain terminal of transistor 315 is coupled to the gate terminal of transistor 310, and the second source/drain terminal of transistor 316 is coupled to the first source/drain terminal of transistor 310 and also to the gate terminal of transistor 309.

The transistors of the pulse generator subcircuit 302 have a low value of the threshold voltage.

The second source/drain terminal of transistor 306 is coupled to a first source/drain terminal of a first power switch n-MOS field-effect transistor 317. The electrical ground potential 318 VSS can be provided to the second source/drain terminal of the first power switch transistor 317. A standby control signal /STB can be applied to the gate terminal of transistor 317.

Transistor 317 of the power switch subcircuit 303 has a high value of the threshold voltage.

A first flip-flop input signal /S can be generated at the gate terminal of the fourth p-MOS pulse generator transistor 310. Furthermore, a second flip-flop input signal /R can be generated at the gate terminal of the third p-MOS pulse generator transistor 309.

The gate terminal of the fourth p-MOS pulse generator 310 is coupled to a gate terminal of a first p-MOS switching transistor 319. The gate terminal of the third p-MOS pulse generator transistor 309 is coupled to the gate terminal of a second p-MOS switching transistor 320.

The first source/drain terminal of the first p-MOS switching transistor 319 is coupled to a first source/drain terminal of a first n-MOS switching transistor 321. Furthermore, a first source/drain terminal of the second p-MOS switching transistor 320 is coupled to a first source/drain terminal of a second n-MOS switching transistor 322. The gate terminal of the first n-MOS switching transistor 321 is coupled to respective first source/drain terminals of a third p-MOS switching transistor 323 and of a third n-MOS switching transistor 324. The gate terminal of the second n-MOS switching transistor 322 is coupled to respective first source/drain terminals of a fourth p-MOS switching transistor 325 and of a fourth n-MOS switching transistor 326. The respective second source/drain terminals of the transistors 323, 319, 320 and 325 can be brought to the electrical potential of the supply voltage 311 VDDL. Furthermore, the second source/drain terminal of the third n-MOS switching transistor 324 is coupled to the second source/drain terminal of the first n-MOS switching transistor 321 and to the second source/drain terminal of the first n-MOS pulse generator transistor 306. The second source/drain terminal of the second n-MOS switching transistor 322 is coupled to the first source/drain terminal of the fourth n-MOS switching transistor 326 and to the second source/drain terminal of the first n-MOS pulse generator transistor 306. The gate terminals of the transistors 323, 324 are coupled to one another and to the first source/drain terminal of the fourth p-MOS pulse generator transistor 310. Furthermore, the gate terminals of the transistors 325, 326 are coupled to one another and to the first source/drain terminal of the third p-MOS pulse generator transistor 309.

It should be noted that transistors 319 to 326 are formed as low threshold voltage transistors. In contrast thereto, the transistors of the flip-flop subcircuit 301 are formed as high threshold voltage transistors.

The flip-flop subcircuit 301 contains a first p-MOS storage transistor 327, a first n-MOS storage transistor 328, a second p-MOS storage transistor 329 and a second n-MOS storage transistor 330. First source/drain terminals of the transistors 327, 328 are coupled to one another and to the gate terminals of the transistors 329, 330. First source/drain terminals of the transistors 329, 330 are coupled to one another and to the gate terminals of the transistors 327, 328. Second source/drain terminals of the transistors 327, 329 can be brought to the electrical potential of the supply voltage 311 VDDL, whereas the second source/drain terminals of the transistors 328, 330 can be brought to the electrical ground potential 318. The first source/drain terminals of the transistors 327, 328 are coupled to the first source/drain terminals of the transistors 319, 321. The first source/drain terminals of the transistors 239, 330 are coupled to the first source/drain terminals of the transistors 322, 320. A first flip-flop output signal Q can be generated at the gate terminals of the transistors 329, 330, whereas a second flip-flop output signal /Q, which is complementary with respect to the first flip-flop output signal Q, can be generated at the gate terminals of the transistors 327, 328.

Furthermore, it should be noted that a signal R, which is complementary with respect to the second flip-flop input signal /R, can be generated at the gate terminal of transistor 321. Furthermore, a signal S, which is complementary with respect to the second flip-flop input signal /S, can be generated at the gate terminal of transistor 322.

The functionality of the circuit arrangement 300 is described below.

The circuit arrangement 200 realizes an improved functionality of a flip-flop with a standby operating state. A permanent storage of storage information of the flip-flop in the standby mode is made possible using a single additional transistor 317 in comparison with a variant without a storage function. Although only a single flip-flop subcircuit 301 is shown in FIG. 3, the power switch subcircuit 301 may be shared by a plurality of flip-flop subcircuits 301 and/or by a plurality of pulse generator subcircuits 302.

The circuitry function of the circuit arrangement 300 is that of an edge-triggered differential flip-flop comprising a pulse generator subcircuit 302 and a set-reset flip-flop subcircuit 301. The output signals of the pulse generator subcircuit 302, /S and /R, are precharged to the potential of the supply voltage 311 VDDL during a precharging phase with a clock signal of the value CLK=“0” via the p-MOS transistors 307, 308. With data signals D and /D having been applied, either the channel of the transistor 312 or that of the transistor 313 conducts, so that, directly after the rising clock edge, either /S or /R is brought to the electrical potential VSSV, which is clearly present at the first source/drain terminal of the first power switch transistor 317. The fourth n-MOS pulse generator transistor 314 has small dimensioning and, after the rising clock edge, generates a coupling of two source/drain terminals of the transistors 315, 316 to one another to VSSV. In this way, the state of the pulse generator subcircuit 302 can no longer be altered after the rising clock edge.

In accordance with the exemplary embodiment described, the set-reset flip-flop is not formed from two feedback NAND gates with two inputs but rather from the two feedback inverters (comprising transistors 327 to 330) of the flip-flop subcircuit 301 and from the switching transistors 323 to 326. Consequently, in each case only one n-MOS or p-MOS transistor is arranged between VDDL and VSSV, respectively, so that the speed with which the load capacitances of the transistors are subjected to charge reversal is increased. For permanent storage of the states Q and /Q, the transistors 327 to 330 of the storage flip-flop subcircuit 301 have minimal dimensioning, a high threshold voltage and a large thickness of the gate-insulating layer. The supply of the flip-flop subcircuit 301 with the supply voltage VDDL 311 and with the real ground potential 318 VSS is not interrupted in the storage flip-flop subcircuit 301 even in the standby mode. The two feedback inverters have the lowest possible leakage currents in a respective production process and are therefore particularly well suited to storing the states Q and /Q in the standby mode. All other subcircuits of the circuit arrangement 300 are switched off in the standby mode, in which the signal /STB=“0” is present at the gate terminal of the transistor 317.

The pulse generator subcircuit 302 is switched off in the standby mode, said subcircuit generating a negative voltage pulse on the /S or /R input on the rising clock edge CLK. Furthermore, the inverters formed from the transistors 323, 324 and 325, 326, respectively, are switched off, which inverters generate a 0-1 pulse on S and R from a 1-0 pulse on /S or /R. What is more, the switching transistors 319 to 322 of the coupling-in subcircuit 304 are switched off in the standby mode. These transistors effect charge reversal of the loads at the outputs Q and /Q in active operation on the rising clock edge and have a low threshold voltage and a thin gate-insulating layer. The clock is set to CLK=“0” in the standby mode.

In comparison with a circuit arrangement without a power switch subcircuit 303, in the circuit arrangement 300 the leakage current in the standby mode decreases depending on the difference between the off currents of the transistors having a low and high threshold voltage by typically two to four decades. What is essential is that the storage flip-flop is not located in the critical propagation path of the circuit. It is precisely this property that is utilized according to the invention in order to form the storage flip-flop from the transistors 327 to 330 which have minimal dimensioning, a high threshold voltage and a thick gate-insulating layer. As a result, the propagation time is reduced compared with the case in which the storage flip-flop is arranged in the critical path. Since the outputs Q and /Q are free prior to charge reversal by the storage flip-flop, but rather are subjected to charge reversal by means of the switching transistors 319 to 322, very short propagation times result. A propagation time of t_{CLKQ}=50 ps at VDDL=1V, or t_{CLKQ}=150 ps at VDDL=0.6V, is expected, by way of example, for a 100 nm CMOS technology. If the first power switch transistor 317 were omitted, a propagation time of t_{CLKQ}=40 ps at VDDL=1V could be achieved. In other words, the propagation time is increased only very slightly despite the use of the first power switch transistor 317. The increase in the propagation time from t_{CLKQ}=40 ps to t_{CLKQ}=50 ps depends on the dimensioning of the first power switch transistor 317 and is thus adjustable. In the case of an application with a high requirement made of leakage current reduction, it is therefore possible to use a power switch transistor 317 with a reduced gate width. By contrast, if the propagation time is of greater importance, then power switch transistors with a large gate width are preferably to be used.

On account of the use of differential circuitry in the pulse generator subcircuit 302 and on account of the fact that no arrangement of a plurality of series-connected transistors is used in the load-sensitive output stage, the circuit arrangement is scalable with regard to the choice of the supply voltage VDDL. The clock load is critically determined by the width of the first power switch transistor 317.

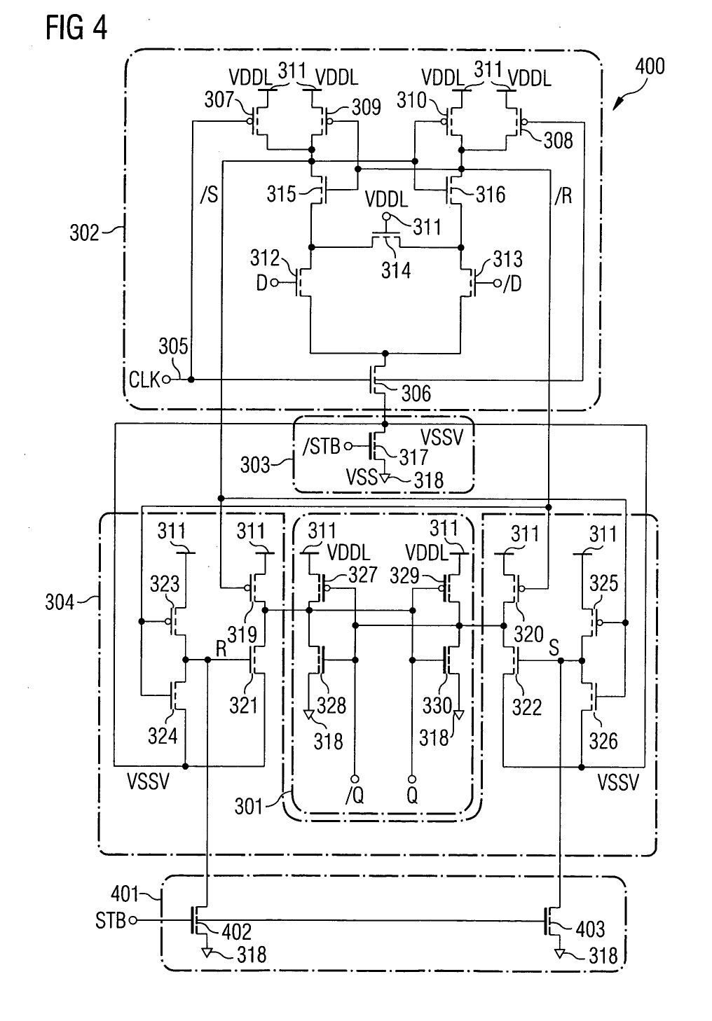

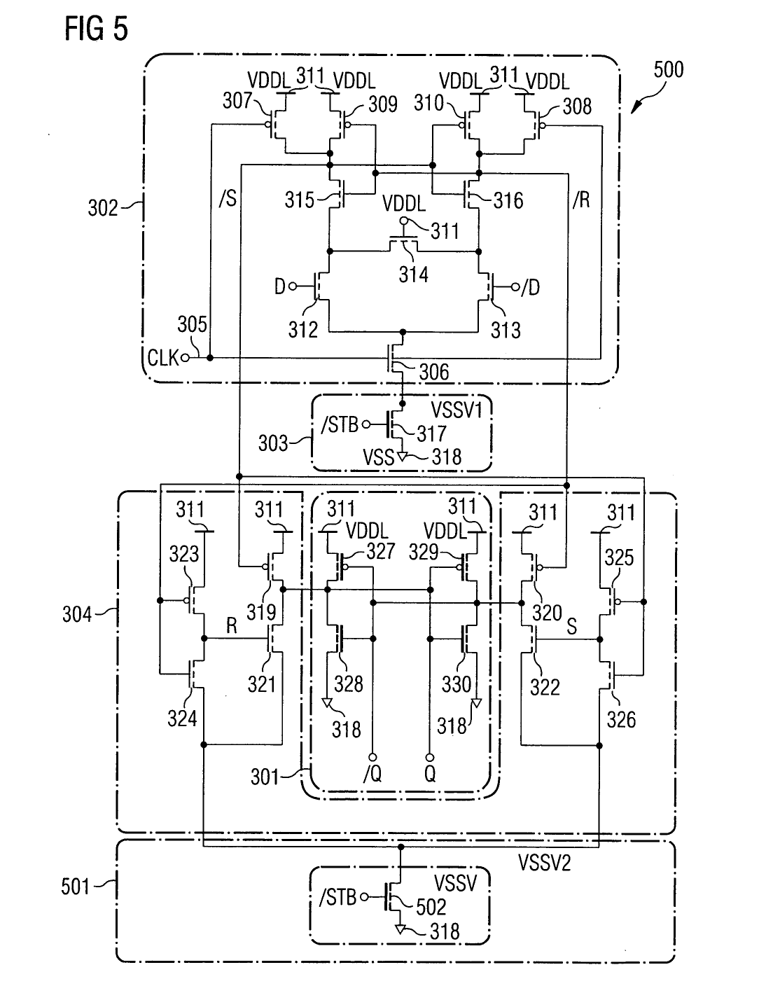

Circuit arrangements 400 to 800 in accordance with second to sixth exemplary embodiments of the invention are described below. They constitute developments with respect to the basic circuit of FIG. 3. The variants of FIG. 4 to FIG. 8, which can be combined with one another as desired, make it possible to enable a favorable realization for the respective application for a given multi-V_{T}/multi-gate-oxide technology. In particular, in the case of a selection of this type, the orders of magnitude of the subthreshold currents and gate tunnelling currents of the different transistor types are to be taken into consideration since these determine, in the standby mode, the time constant with which the virtual ground potential VSSV is charged to the maximum value VDDL-VT0N, where VT0N is the threshold voltage value. This operation has the effect that the nodes S and R experience a rising electrical potential with transistors 324, 326 having been opened, so that the switching transistors 321, 322 can turn on. Since the switching transistors have considerably greater dimensioning than the storage transistors 327 to 330, this may lead, in the extreme case, to the stored states Q and /Q being influenced, that is to say to the storage content being influenced. The circuit arrangements which are described below with reference to FIG. 4 to FIG. 6 contain circuitry countermeasures for maintaining the storage content in the flip-flop in a manner free of disturbances.

A circuit arrangement 400 in accordance with a second exemplary embodiment of the invention is described below with reference to FIG. 4.

In addition to the components shown in FIG. 3, the circuit arrangement 400 has a reference potential circuit 401, which provides the gate terminals of the transistors 321 and 322, respectively, with defined electrical potentials. The reference potential circuit 401 contains a first n-MOS reference potential transistors 402 and a second n-MOS reference potential transistor 403. The signal STB, which is the inverse of the standby signal /STB, can be applied to the gate terminals of the transistors 402, 403. First source/drain terminals of the n-MOS reference potential transistors 402, 403 can be brought to the electrical ground potential VSS 318. A second source/drain terminal of the first n-MOS reference potential transistor 402 is coupled to the gate terminal of the first n-MOS switching transistor 321. A second source/drain terminal of the second n-MOS reference potential transistor 403 is coupled to a gate terminal of the second n-MOS switching transistor 322.

The functionality of the reference potential circuit 401 is to be seen in the fact that the nodes S and R can be brought to the electrical ground potential VSS 318 by means of the transistors 402 and 403, respectively. In this case, all the inputs of the switching transistors 319 to 322 have a defined electrical potential. A loss of the storage content of the flip-flop can thus be reliably avoided since all the switching transistors are closed in the standby mode. Consequently, on account of the functionality of the reference potential circuit 401, the switching transistors 321, 322 are completely turned off even when the virtual ground VSSV is charged on account of leakage currents to the voltage level VDDL minus the threshold voltage VT0N.

The reference potential transistors 402, 403, which may also be referred to as additional power switch transistors, have a high threshold voltage and a high thickness of the gate-insulating layer.

A circuit arrangement 500 in accordance with a third exemplary embodiment of the invention is described below with reference to FIG. 5.

The circuit arrangement 500 differs from the circuit arrangement 300 essentially by the fact that a reference potential circuit 501 is provided as an additional component. The reference potential circuit 501 contains a second n-MOS power switch transistor 502, which is essentially configured in the same way as the first power switch transistor 317. The standby signal /STB can be applied to the gate terminal of the second power switch transistor 502. A first source/drain terminal of the second power switch transistor 502 is coupled to the second source/drain terminals of the transistors 324, 326, 321, 322. A second source/drain terminal of the second power switch transistor 502 is at the electrical ground potential VSS.

A further important difference between the circuit arrangement 500 and the circuit arrangement 300 is that that line which is coupled to transistor 317 and on which the virtual ground potential VSSV is provided in accordance with FIG. 3 is free of a coupling to transistors 324, 326, 321, 322 in accordance with FIG. 5. In other words, those lines on which the virtual ground potentials of the first power switch transistors 317 and of the pulse generator circuit 302, on the one hand, and of the coupling-in subcircuit 304, on the other hand, are provided are now separated. In FIG. 5, the virtual ground potential of the first power switch transistor 317 and of the pulse generator circuit 302 is designated by VSSV1. By contrast, the virtual ground potential of the coupling-in subcircuit 304 is designated by VSSV2 in FIG. 5. The voltage rise to VSSV2 can be slowed down by means of the separation of the virtual grounds into VSSV1 and VSSV2. In accordance with FIG. 5, the leakage current path which can charge the virtual ground VSSV2 to VDDL minus the threshold voltage VT0N is formed only by the p-MOS transistors 309, 320, 323, 325. The − in accordance with FIG. 5—lower source/drain terminals of the transistors 324, 321, 322, 326 are provided with a defined electrical potential using the second power switch transistor 502, which is realized as a transistor having a high value of the threshold voltage and a large thickness of the gate-insulating layer. The exemplary embodiment of FIG. 5 affords advantages particularly in the case of small transistors with very low leakage currents and in the case of an application with a rather short standby time. The separation of the virtual grounds of the pulse generator circuit 302 and of the set-reset flip-flop 301, 304 makes it more difficult to charge the virtual ground VSSV2 to VDDL minus VT0N in the standby mode on account of leakage currents.

It should be noted that the virtual ground line VSSV1 can be shared with gates in the logic path. It is possible to operate a plurality of pulse generator circuits with the same virtual ground line.

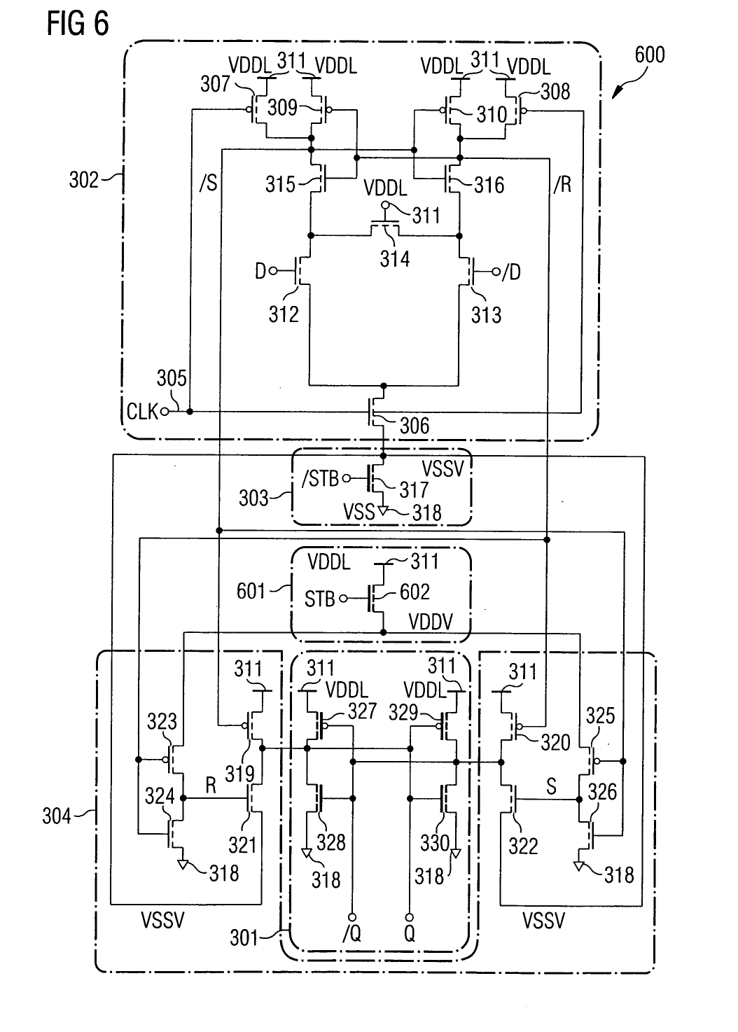

A circuit arrangement 600 in accordance with a fourth exemplary embodiment of the invention is described below with reference to FIG. 6.

The circuit arrangement 600 differs from the circuit arrangement 500 shown in FIG. 5 essentially by the fact that a reference potential circuit 601 with a third p-MOS power switch transistor 602 is provided instead of the reference potential circuit 501 with the second n-MOS power switch transistor 502. The third power switch transistor 602 is a transistor having a high threshold voltage, to whose gate terminal a signal STB can be applied, which signal is complementary with respect to the standby signal /STB that can be applied to the gate terminal of the first power switch transistor 317. A first source/drain terminal of the third power switch transistor 602 can be brought to the potential of the first electrical supply voltage VDDL 311, whereas the second source/drain terminal of the third p-MOS power switch transistor 602 is coupled to the − in accordance with FIG. 6—upper source/drain terminals of the transistors 323, 325. The electrical potential of the second source/drain terminal of the third power switch transistor 602 is the virtual supply voltage potential VDDV. The − in accordance with FIG. 6—lower source/drain terminals of the transistors 321, 322, which are coupled to the − in accordance with FIG. 6—upper source/drain terminal of the first power switch transistor 307, can be provided with the virtual ground potential VSSV.

Instead of the n-MOS power switch transistor 502 from FIG. 5, in FIG. 6 use is made of a p-MOS power switch 602, by means of which the inverters for generating the signals S and R are coupled to a virtual supply voltage VDDV. A major advantage of this exemplary embodiment is that a respective source/drain terminal of the transistors 324, 326 is coupled to the real ground VSS 318, as a result of which a defined electrical potential is provided to these nodes in the standby mode. Therefore, the circuit arrangement 600 is particularly well suited to applications in which long standby times can occur. In order, in active operation, to avoid a rise in the CLK-Q or CLK-/Q propagation time on account of a slowed-down 0-1 transition on S or R, the power switch 602 is dimensioned in accordance with the requirements made of the propagation time.

The transistors 324, 326, which are realized as low threshold voltage transistors in accordance with FIG. 6, may alternately have a high threshold voltage and a large thickness of the gate-insulating layer. In this case, the gate tunnelling current is also prevented via the gate terminal of the transistors 324, 326. Since, in active operation, only a 1-0 transition in each case takes place on /S or /R, the CLK-Q or CLK-/Q propagation time of the flip-flop is not increased on account of this measure.

In the circuit arrangement 600, the inverters for generating the signals R and S have a terminal for the ground potential VSS and are operated with a virtual supply voltage VDDV via a third p-MOS power switch transistor 602. In the standby mode, the transistors 324, 326 are opened since /S and /R are precharged to VDDL. The nodes S and R are at the electrical ground potential VSS 318 and therefore turn off the n-MOS storage transistors 321, 322. The leakage current through the closed p-MOS transistors 323, 325 of the inverters is prevented by means of the p-MOS power switch 602.

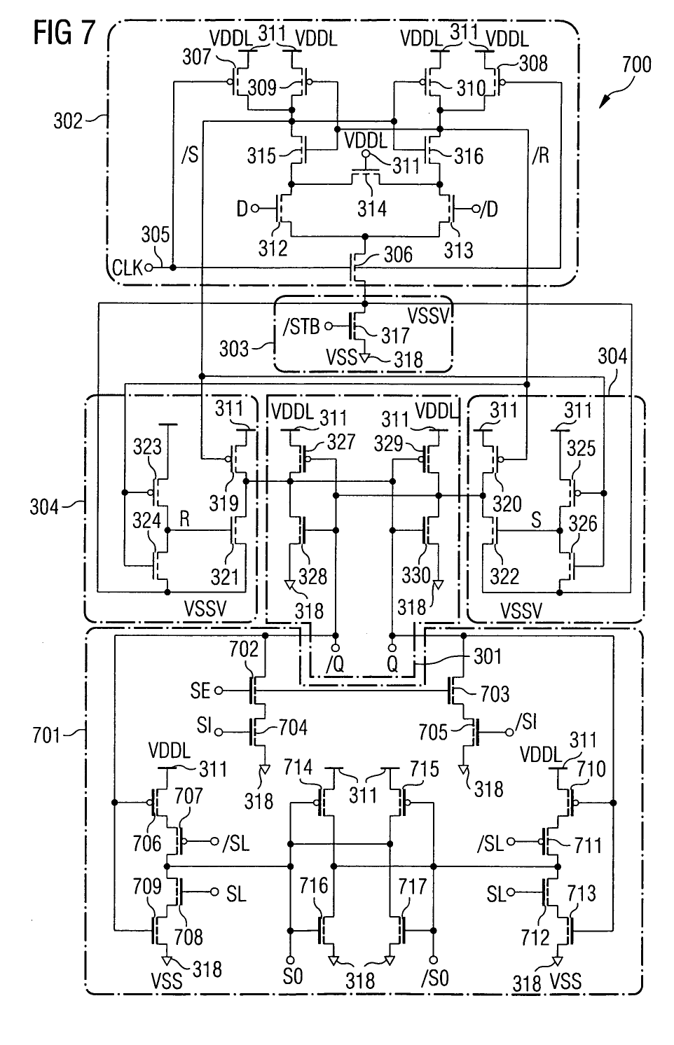

A circuit arrangement 700 in accordance with a fifth exemplary embodiment of the invention is described below with reference to FIG. 7.

In the circuit arrangement 700, the subcircuits 301 to 304 are realized as in FIG. 3. A scan path subcircuit 701 is formed in addition to these components, said scan path subcircuit being coupled to the output nodes Q, /Q of the flip-flop subcircuit 301.

The node with the output signal /Q is coupled to a first source/drain terminal of a first n-MOS scan path transistor 702. An enable signal SE can be applied to the gate terminal of the first n-MOS scan path transistor 702 and to the gate terminal of a second n-MOS scan path transistor 703. A first source/drain terminal of the second n-MOS scan path transistor 703 is coupled to the node Q of the flip-flop subcircuit 301. A second source/drain terminal of the first n-MOS scan path transistor 702 is coupled to a first source/drain terminal of a third n-MOS scan path transistor 704, the second source/drain terminal of which can be brought to the electrical ground potential VSS 318. A scan input signal SI can be applied to the gate terminal of the third n-MOS scan path transistor 704. Furthermore, a second source/drain terminal of the second n-MOS scan path transistor 703 is coupled to a first source/drain terminal of a fourth n-MOS scan path transistor 705. A signal /SI, which is complementary with respect to the scan input signal SI, can be applied to the gate terminal of the fourth n-MOS scan path transistor 705. The second source/drain terminal of the fourth n-MOS scan path transistor 705 can be brought to the electrical ground potential VSS 318.

The first source/drain terminal of the first n-MOS scan path transistor 702 is coupled to the gate terminal of a first p-MOS scan path transistor 706. A first source/drain terminal of the first p-MOS scan path transistor 706 can be brought to the electrical potential of the supply voltage VDDL 311. A second source/drain terminal of the first p-MOS scan path transistor 706 is coupled to a first source/drain terminal of a second p-MOS scan path transistor 707, to the gate terminal of which a signal /SL can be applied. A second source/drain terminal of the second p-MOS scan path transistor 707 is coupled to a first source/drain terminal of a fifth n-MOS scan path transistor 708. A signal SL, which is the inverse of the signal /SL, can be applied to the gate terminal of the fifth n-MOS scan path transistor 708. The second source/drain terminal of the fifth n-MOS scan path transistor 708 is coupled to a first source/drain terminal of a sixth n-MOS scan path transistor 709, the second source/drain terminal of which can be brought to the electrical ground potential VSS 318. The gate terminal of the sixth n-MOS scan path transistor 709 is coupled to the gate terminal of the first p-MOS scan path transistor 706.

The first source/drain terminal of the second n-MOS scan path transistor 703 is coupled to the gate terminal of a third p-MOS scan path transistor 710. A first source/drain terminal of the third p-MOS scan path transistor 710 can be brought to the electrical potential of the supply voltage VDDL 311. The second source/drain terminal of the third p-MOS scan path transistor 710 is coupled to a first source/drain terminal of a fourth p-MOS scan path transistor 711, to the gate terminal of which the signal /SL can be applied. A second source/drain terminal of the fourth p-MOS scan path transistor 711 is coupled to a first source/drain terminal of a seventh n-MOS scan path transistor 712, to the gate terminal of which a signal SL can be applied. A second source/drain terminal of the seventh n-MOS scan path transistor 712 is coupled to a first source/drain terminal of an eighth n-MOS scan path transistor 713, the second source/drain terminal of which can be brought to the electrical ground potential VSS 318. The gate terminal of the eighth n-MOS scan path transistor 713 is coupled to the gate terminal of the third p-MOS scan path transistor 710.

Furthermore, the second source/drain terminal of the second p-MOS scan path transistor 707 is coupled to the gate terminal of a fifth p-MOS scan path transistor 714. A first source/drain terminal of the fifth p-MOS scan path transistor 714 can be brought to the electrical potential of the supply voltage 311. Furthermore, a second source/drain terminal of the fifth p-MOS scan path transistor 714 is coupled to a first source/drain terminal of a ninth n-MOS scan path transistor 716, the second source/drain terminal of which can be brought to the electrical ground potential VSS 318. The gate terminal of the ninth n-MOS scan path transistor 716 is coupled to the gate terminal of the fifth p-MOS scan path transistor 714. An output signal SO is provided at the gate terminal of the ninth n-MOS scan path transistor 716.

The second source/drain terminal of the fourth p-MOS scan path transistor 711 is coupled to the gate terminal of a sixth p-MOS scan path transistor 715, the first source/drain terminal of which can be brought to the electrical potential of the supply voltage VDDL 311. The second source/drain terminal of the sixth p-MOS scan path transistor 715 is coupled to the gate terminal of the ninth n-MOS scan path transistor 716. Furthermore, the second source/drain region of the sixth p-MOS scan path transistor 715 is coupled to a first source/drain terminal of a tenth n-MOS scan path transistor 717, the second source/drain terminal of which can be brought to the electrical ground potential VSS 318. The gate terminal of the tenth n-MOS scan path transistor 717 is coupled to the gate terminal of the sixth p-MOS scan path transistor 715. The output signal /SO, which is complementary with respect to the output signal SO, is provided at these gate terminals.

Furthermore, the second source/drain terminal of the sixth p-MOS scan path transistor 715 is coupled to the second source/drain terminal of the second p-MOS scan path transistor 707.

The functionality of the circuit arrangement 700, in particular of the scan path subcircuit 701, is described below.

Clearly, the scan path subcircuit 701 serves for checking the functionality of the rest of the circuit arrangement, in particular of the flip-flop subcircuit 301. For this purpose, a signal may be written to the flip-flop subcircuit 301 and the signal may subsequently be read out again for test purposes.

Even though in FIG. 7 the scan path extension 701 is illustrated for the circuit arrangement 300 shown in FIG. 3, such an extension can be combined with any other exemplary embodiment of the circuit arrangement according to the invention by a scan path subcircuit 701 being coupled to the nodes Q, /Q of the respective circuit arrangement in a manner analogous to the manner shown in FIG. 7.

The scanability of a flip-flop circuit is advantageous in a complex circuit in order to construct a scan path for testing the integrated circuit from input and output registers. Since such a test is rather non-time-critical in comparison with the active operation of the circuit arrangement 700, all the transistors 702 to 717 have minimal dimensioning, a high threshold voltage and a gate-insulating layer having a large thickness.

The inputs of the scan path subcircuit 701 are coupled to the outputs Q and /Q of the set-reset flip-flop 301. The scan input region contains the transistors 702 to 705. The scan mode is switched on by means of the signal SE. During the scan mode, the pulse generator subcircuit 302 is generally switched off (CLK=“0”,/STB=“0”). The set-reset flip-flop 301, i.e., the nodes Q and /Q, is written to by means of the inputs SI and /SI of the transistors 704, 705.

The transistors 327 to 330, 702 to 705 together with the transistors 706 to 717 form a master-slave arrangement. In this case, transistors 327 to 330, 702 to 705 form the master stage, whereas the transistors 706 to 717 form the slave stage. The slave stage accepts the read-in states SI and /SI on the rising edge with respect to SL=“1” and /SL=“0”. A scan flip-flop is formed from the transistors 714 to 717 in the form of two feedback inverters. The transistors 706 to 709 and the transistors 710 to 713 in each case form a so-called C²MOS latch (“clocked CMOS latch”) which controls the data propagation to the scan flip-flop. As soon as the two C²MOS latches are opened, the master stage blocks the coupling to the scan inputs SI and /SI by means of SE=“0”. The clocks of the scan path SL and SE=/SL are thus the inverse of one another. The signal SL=/SE may for example be generated locally by means of an inverter from the scan enable signal SE or be forwarded globally to all the flip-flops (not shown in FIG. 7).

In order to form the scan paths in an input or output register having a width of n bits, the scan outputs SO and /SO of a stage i are respectively connected up to the scan inputs SI and /SI of a stage i+1 in such a way that a shift register is formed. In this way, data can be progressively written for test purposes to the entire data path within n scan clock cycles, defined by means of the SE signal.

In contrast to the arrangement disclosed in R. Zyuban et al. for an edge-triggered differential flip-flop, the arrangement of the scan extension as shown in FIG. 7 is completely symmetrical. The invention's implementation of the scan path subcircuit 701 comprising transistors having a high threshold voltage and a high thickness of the gate-insulating layer is essential. In view of only six additional leakage current paths from VDDL to VSS, the scan path subcircuit 701 only very slightly increases the power loss relative to the circuit arrangement 300.

In comparison with a flip-flop without a scan path (circuit arrangement 300), only two loads are situated at the outputs Q and /Q with the parasitic drain capacitances of the scan enable transistors 702, 703, which loads are negligible to a good approximation. A sufficiently rapid propagation of signals through the scan extension 701 is thus ensured.

Although a higher number of additional transistors is necessary in the scan path subcircuit 701 than in the case of the solution disclosed in S. Shigematsu et al., an increase in the propagation time can be observed in the case of the scan path disclosed in S. Shigematsu et al. since the transistors of the scan path extension do not have minimal dimensioning, in contrast to the scan path subcircuit 701 shown in FIG. 7. Furthermore, in accordance with S. Shigematsu et al., the construction of the scan path from the output of the slave latch to the scan input of the master latch of the subsequent stage always loads the output of the slave latch and thus reduces the effective driver capability. The consequence of this is that the scaling behavior of the scan path subcircuit 701 with regard to smaller supply voltages is better according to the invention than according to S. Shigematsu et al.

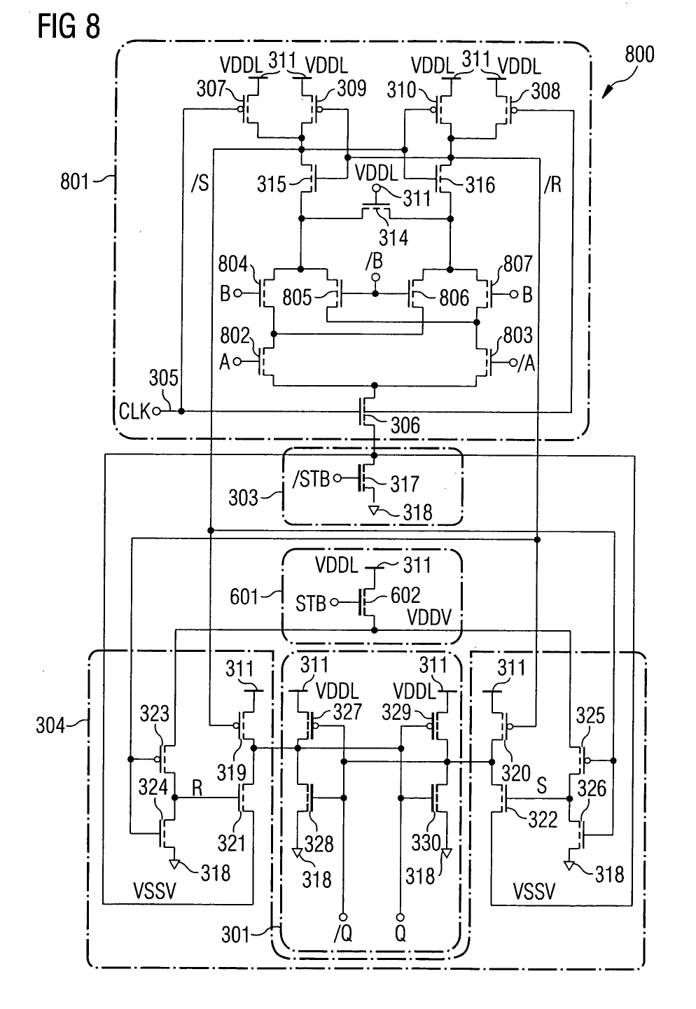

A circuit arrangement 800 in accordance with a sixth exemplary embodiment of the invention is described below with reference to FIG. 8.

In the circuit arrangement 800, the subcircuits 303, 301, 304 are formed as in the circuit arrangement 600. Instead of the pulse generator subcircuit 302, a pulse generator subcircuit 801 is formed in the circuit arrangement 800. Said pulse generator subcircuit corresponds to the pulse generator subcircuit 303 with the difference that transistors 312, 313, by means of which the data signals D and /D are coupled in in accordance with FIG. 6, are replaced by first to sixth n-MOS logic transistors 802 to 807.

The first source/drain terminal of the first n-MOS pulse generator transistor 306 is coupled to a respective first source/drain terminal of a first and of a second n-MOS logic transistor 802, 803. A first data signal A can be applied to the gate terminal of the first n-MOS logic transistor 802. A signal /A, which is complementary with respect to the first data signal A, can be applied to the gate terminal of the second n-MOS logic transistor 803. The second source/drain terminal of the first n-MOS logic transistor 802 is coupled to a first source/drain terminal of a third n-MOS logic transistor 804. The second source/drain terminal of the third n-MOS logic transistor 804 is coupled to a first source/drain terminal of a fourth n-MOS logic transistor 805, the second source/drain terminal of which is coupled to the second source/drain terminal of the second n-MOS logic transistor 803 and to a first source/drain terminal of a sixth n-MOS logic transistor 807. A second data signal B can be applied to the gate terminal of the third n-MOS logic transistor 804. A signal /B, which is complementary with respect to the second data signal B, can be applied to the gate terminals of the fourth and fifth n-MOS logic transistors 805, 806. The second source/drain terminal of the first n-MOS logic transistor 802 is coupled to a first source/drain terminal of the fifth n-MOS logic transistor 806, the second source/drain terminal of which is coupled to a second source/drain terminal of the sixth n-MOS logic transistor 807. The data signal B is applied to the gate terminal of the sixth n-MOS logic transistor 807. Furthermore, a second source/drain terminal of the second n-MOS logic transistor 803 is coupled to a first source/drain terminal of the sixth n-MOS logic transistor 807. The second source/drain terminals of the transistors 804, 805 are coupled to the first source/drain terminal of the fourth n-MOS pulse generator transistor 314. Furthermore, the second source/drain terminal of the fourth n-MOS pulse generator transistor 314 is coupled to the second source/drain terminals of the fifth and sixth n-MOS logic transistors 806, 807.

The functionality of the circuit arrangement 800 is described below.

The circuit arrangement 800 is a circuit arrangement with an integrated logic function in the input stage 801. In accordance with the exemplary embodiment described, an XOR/XNOR function with two input signals A, B is carried out using a logic functionality of the transistors 802 to 807. In principle, it is possible to implement any Boolean function in the form of a functional logic in each of the circuits 300 to 800. However, it should be ensured that, for every possible input bit pattern, only one of the two source/drain terminals of the transistors 305, 306 is coupled to VSSV via the logic path, so that only a single conductive path exists from one of the source/drain terminals via the logic path to the virtual ground VSSV for CLK=“1”.

Consequently, it is clearly possible to implement a logic stage in the pulse generator subcircuit 302.

A description is given below of the technological realization of the circuit arrangements 300 to 800 in accordance with a preferred exemplary embodiment of the invention.

Each of the circuit arrangements 300 to 800 is suitable, in principle for any desired combination of different MOS field-effect transistor types having different threshold voltages and thicknesses of the gate-insulating layer.

The following implementation possibilities should be mentioned by way of example:

a) the above-described exemplary embodiments are based on a process in which two transistor types (respectively n-MOS and p-MOS) having at least two different values of threshold voltages and having different thicknesses of the gate-insulating layer are made available.

b) In a process in which only one transistor type (p-MOS or n-MOS) having a high threshold voltage is provided, it is possible to reduce the threshold voltages of the transistors in the critical path of the circuit arrangement, that is to say in the case of the pulse generator and switching transistors, by means of the so-called forward biasing method. For an n-MOS transistor, a positive voltage is applied to the bulk contact for this purpose. For a p-MOS transistor, a negative voltage is applied to the bulk contact for this purpose. A triple well process is advantageous in this scenario.

c) In principle, the low leakage currents required in the storage flip-flop, in the scan path, and also in the power switch transistors can also be achieved using the so-called reverse biasing method of transistors having a low threshold voltage.

d) When using SOI-based (“silicon on insulator”) double gate transistors instead of bulk MOS transistors, a desired threshold voltage can be established for each transistor depending on the operating state. In the case of a double gate transistor, however, the threshold voltage is not shifted via a bulk contact, but rather via the back gate. The back gate voltages may be chosen depending on the operating state (active/standby) in accordance with table 1.

| | n-MOS | | p-MOS | |
|---|---|---|---|---|
| Operating | Back | Threshold | Back | Threshold |
| state | gate | voltage | gate | voltage |
| VGBN | VT0N | VGBP | VT0P | |
| Active:/STB = 1 | ≧VDDL | Low | ≦0 V | Low |
| Standby:/ | ≦0 V | High | ≧VDDL | High |
| STB = 0 | | | | |

For a sufficiently thick back-gate-insulating layer, the power switch transistor 317 may even be completely omitted if the clock, as is provided for the flip-flop, is set to V_{CLK}=0V in the standby mode. Provided that a negative voltage is present simultaneously at the back gate of the clock transistor 306, the threshold voltage thereof increases and prevents the leakage current of the pulse generator. The leakage currents of the transistors 324, 321, 322, 326 are also minimized by a strongly negative back gate voltage.

The abovementioned implementation possibilities b) to d) presuppose that the transistors have a sufficiently thick gate-insulating layer and the electric current in the switched-off state is not dominated by the gate leakage current, since only the subthreshold component of the overall leakage current can be altered in all three cases. If transistors having thin gate-insulating layers and high gate leakage currents are used, a power switch transistor having a sufficiently thick gate-insulating layer is always necessary.

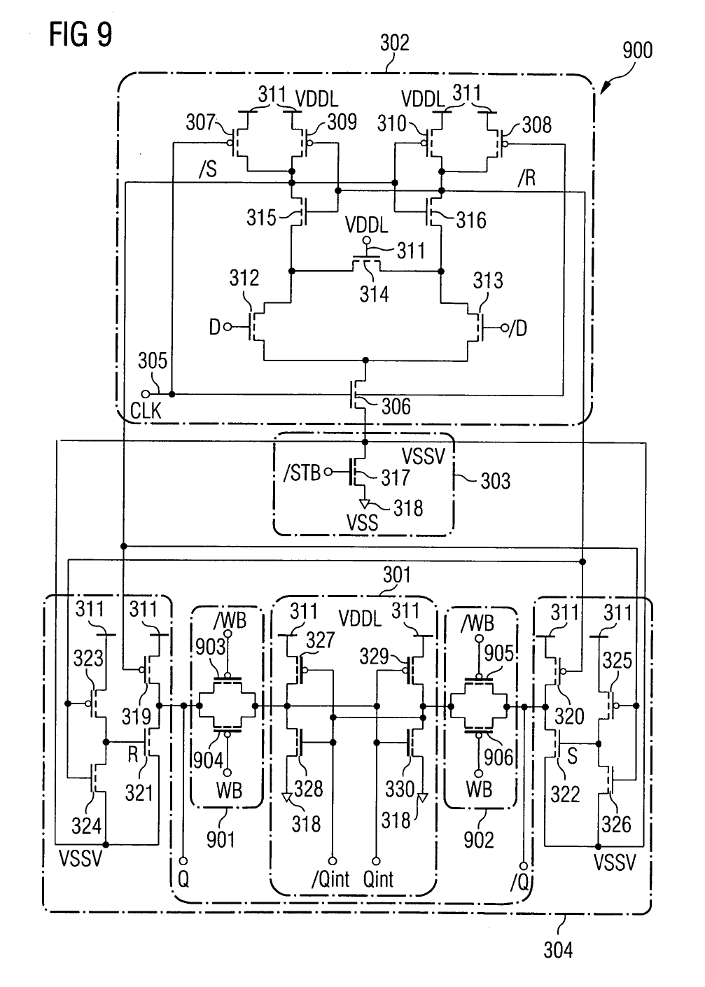

A circuit arrangement 900 in accordance with a seventh exemplary embodiment of the invention is described below with reference to FIG. 9.

The circuit arrangement 900 differs from the circuit arrangement 300 shown in FIG. 3 essentially by the fact that a first and a second transmission gate subcircuit 901 and 902, respectively, are connected between the flip-flop subcircuit 301 and the coupling-in subcircuit 304. To put in another way, the first transmission gate subcircuit 901 is connected between the two source/drain terminals—coupled to one another—of the first p-MOS switching transistor 319 and of the first n-MOS switching transistor 321, on the one hand, and the two source/drain terminals—coupled to one another—of the first p-MOS storage transistor 327 and of the first n-MOS storage transistor 328. Said first transmission gate subcircuit 901 is formed from two transistors connected in parallel with one another, namely the first p-MOS protection transistor 903 and the first n-MOS protection transistor 904. First source/drain terminals of the transistors 903, 904 are coupled to one another. Furthermore, second source/drain terminals of the two transistors 903, 904 are coupled to one another. Control signals WB and /WB can be applied to gate terminals of the transistors 903, 904. The control signals WB and /WB are complementary with respect to one another, and the two transistors 903, 904 that can be driven with these control signals are also of different conduction types. Therefore, with control signals WB, /WB having been applied, either both transistors 903, 904 are opened or both are closed.

Furthermore, a second transmission gate subcircuit 902 is provided in FIG. 9, in the case of which a second p-MOS protection transistor 905 and a second n-MOS protection transistor 906 are connected in parallel with one another, first source/drain terminals of the transistors 905, 906 being coupled to one another, and second source/drain terminals of the transistors 905, 906 being coupled to one another. The first source/drain terminals—coupled to one another—of the transistors 905, 906 are coupled to the source/drain terminals—coupled to one another—of the second p-MOS storage transistor 329 and of the second n-MOS storage transistor 330. Furthermore, the second source/drain terminals—coupled to one another—of the transistors 905, 906 are coupled to the source/drain terminals—coupled to one another—of the second p-MOS switching transistor 320 and of the second n-MOS switching transistor 322. In the second transmission gate subcircuit 902, too, the control signals WB, /WB applied to the gate terminals of the transistors 905, 906 are complementary with respect to one another, so that, on account of the complementary conductivity types of the transistors 905, 906, both transistors 905, 906 are either opened or turned off.

As is furthermore shown in FIG. 9, the transistors 903 to 906 of the transmission gate subcircuits 901, 902 are provided with a high threshold voltage value, so that, in the blocking state, they turn off particularly reliably and have only negligible leakage currents.

The circuit arrangement 900 provides a sense-amplifier-based flip-flop with a storage functionality in the standby mode, in which the inverters—having feedback between one another—of the flip-flop circuit 301 (a first inverter is formed from the transistors 327, 328 and a second inverter is formed from the transistors 329, 330) are coupled to the switching transistors 319, 321 and 320, 322, respectively, via the transmission gate subcircuits 901, 902.

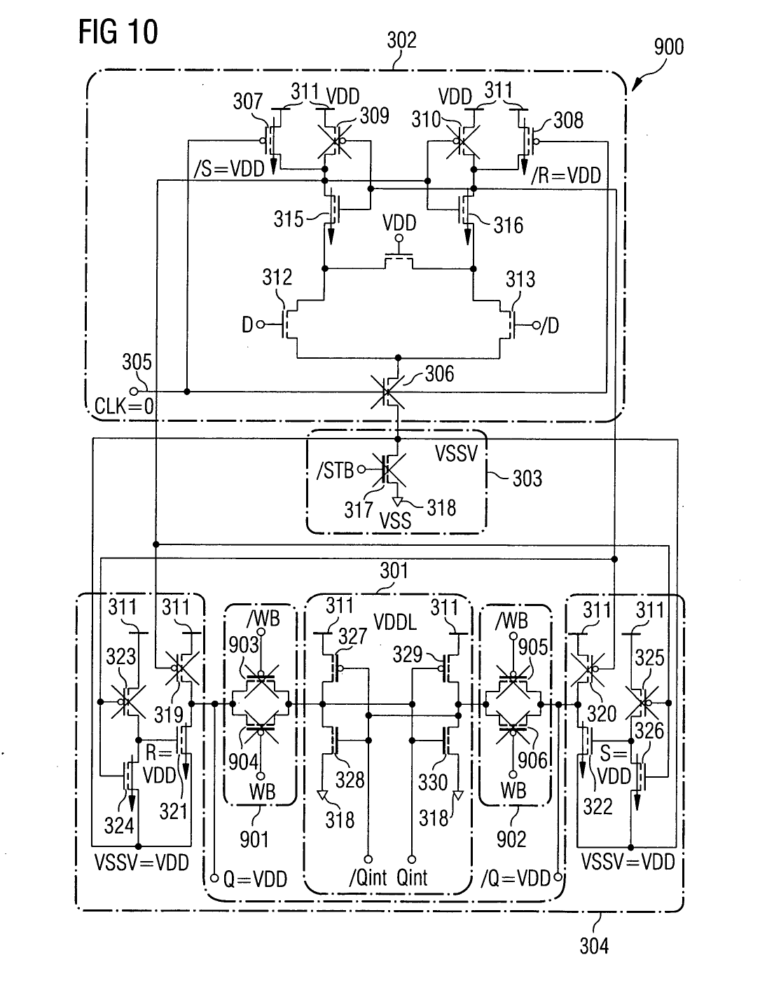

The two transmission gates 901, 902 comprising the transistors 903, 904 and 905, 906, respectively, are interposed between the two feedback inverters 327, 328, on the one hand, and 329, 330, on the other hand, which are produced from low-leakage-current transistors having a thick gate-insulating layer and having a high threshold voltage value. The task of the transmission gates 901, 902 is to decouple the feedback inverters 327, 328 and 329, 330, respectively, from the remaining components of the circuit arrangement during the standby state. This reliably avoids undesirable overwriting of a storage content in the flip-flop subcircuit 301 on account of a virtual supply voltage that has floated to V_{SSV}=V_{DD}. The digital control signals of the transmission gate subcircuits 901, 902 are put at WB=“1” and /WB=“1” for this purpose. This operating state is shown in FIG. 10, where it is illustrated in a drawing that the transmission gate subcircuits 901, 902 turn off in this operating state. The electrical potential with the logic value “0” of WB and the electrical potential with the logic value “1” of /WB may also lie below V_{SS} and above V_{DD}, respectively, thereby generating a negative absolute gate-source voltage at the transistor pairs 903, 904 and 905, 906, respectively.

During active operation of the circuit arrangement 900, the two transmission gate subcircuits 901, 902 are switched on by application of the control signals WB=“1” and /WB=“0”, so that the feedback inverters 327, 328 and 329, 330 are coupled via the conductive channel regions of the transistors 903 to 906 to the respective drain terminals of the switching transistors 319, 321 and 320, 322. The control signal with a logic value “0” of /WB and the control signal with a logic value “1” of WB may also lie below V_{SS} and above V_{DD}, respectively, thereby achieving an increased gate overdrive V_{GS}-V_{T}, where V_{T} is the threshold voltage of the associated transistor and V_{GS} is the gate-source voltage. This effects a lower-impedance coupling of the switching transistors 319 to 322 to the feedback inverters 327 to 330.

Like the two feedback inverters 327 to 330, the transmission gate subcircuits 901, 902 are formed from low-leakage-current transistors having a thick gate-insulating layer and thus having a high threshold voltage value and are preferably grouped together in the circuit layout, so that only one region having a thick gate oxide layer and/or a relatively high threshold voltage is generated. This ensures a high area efficiency since, in circuit components of this type, minimum distances are required between transistors and different gate oxide thicknesses.

In the standby state, only subthreshold currents (typically 10 pA per μm transistor width in 90 nm CMOS technology) of the turned-off transmission gate subcircuits 901, 902 flow into the feedback inverters 327 to 330. This electric current is quite generally insufficient to overwrite the storage content at the nodes Qᵢₙₜ and /Qᵢₙₜ shown in FIG. 9. In order to clarify the functional principle, both the external flip-flop outputs Q and /Q and the internal storage nodes Qᵢₙₜ and /Qᵢₙₜ are illustrated in FIG. 9, FIG. 10. Logic gates are driven by means of the external outputs Q and /Q. Should the stable signals Qᵢₙₜ and /Qᵢₙₜ be required in a logic block during the standby state, then they can be coupled in there via transistors having a preferably thick gate oxide layer. No additional gate leakage current path is produced in this case.

In the standby mode of the circuit arrangement 900 as shown in FIG. 10, the external outputs Q and /Q and also the virtual supply voltage V_{SSV} have floated to V_{DD}, for example after approximately 10 μs. The transmission gate subcircuits 901, 902 clearly prevent the overwriting of the storage content at Qᵢₙₜ and /Qᵢₙₜ.

The circuit arrangement 900 has the advantage over the circuit arrangement 300 that the situation in which the switching transistors 321, 322 of the flip-flop in the output stage can overwrite the storage content of the inverters 327 to 330 even in the case of unfavorable dimensionings or process variations is reliably avoided in the case of the circuit arrangement 900.

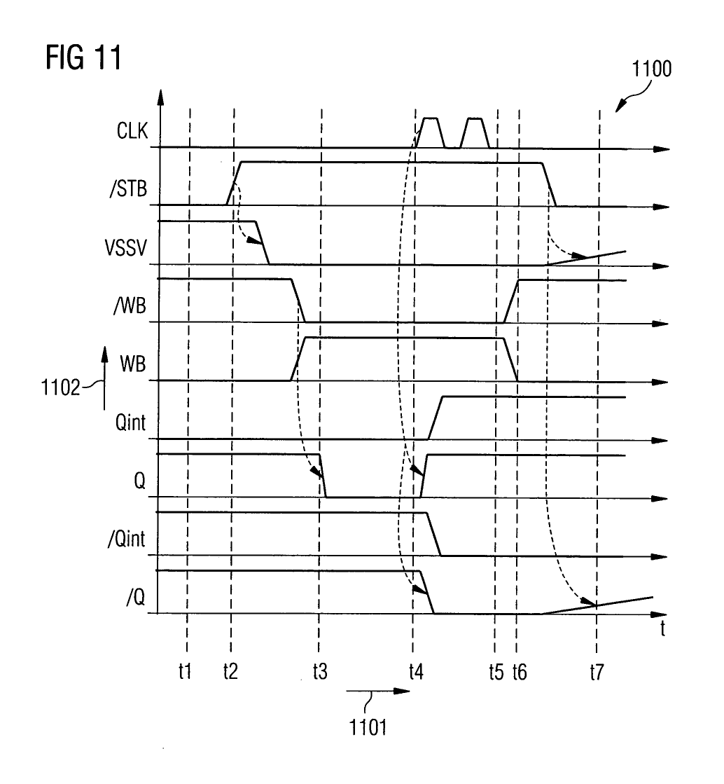

A timing diagram 1100 is described below with reference to FIG. 11.

FIG. 11 reveals the reactivation of the circuit arrangement 900 from the standby state, the active operation and the decoupling of the inverters 327, 328 and 329, 330. The active phase (oscillating clock signal) usually extends over many clock cycles (often more than 1000). The charging of the virtual supply voltage lasts for approximately 10 μs to 50 μs in modern technologies.

In the timing diagram 1100, the time is plotted along a time axis 1101, and different signals which can be applied to terminals of the circuit arrangement 900 are plotted along a signal axis 1102. The designations of the signals (/Q, /Qᵢₙₜ, Q, Qᵢₙₜ, WB, /WB, VSSV, /STB, CLK) in FIG. 11 correspond to the designations in the circuit arrangement 900 in FIG. 9, FIG. 10.

The timing diagram 1100 is described in more detail below.

The time range t1 to t3 represents the reactivation of the flip-flop, the time interval from t4 to t5 represents the active operation, and the time interval from t6 to t7 represents the initiation of a standby state.

Before the instant t1, the circuit arrangement 900 is in the standby mode, in which Q, /Q and V_{SSV} have floated to V_{DD}. Qᵢₙₜ and /Qᵢₙₜ hold a defined state.

At the instant t2, the first power switch transistor 317 is opened. V_{SSV} is charged to V_{SS}. The switching transistors 319 to 322 are closed owing to the low clock signal CLK=“0”.

At the instant t3, the transistors 903 to 906 of the transmission gate subcircuits 901, 902 are opened. The storage content from Qᵢₙₜ and /Qᵢₙₜ is transferred to Q and /Q.

At the instant t4, the clock signal CLK is active. This effects a state change at Q and /Q on account of changed input data.

At the instant t5, the clock signal CLK is stopped, so that the switching transistors 319 to 322 of the output stage are closed.

At the instant t6, the transistors 903 to 906 of the transmission gate subcircuits 901, 902 are closed. Qᵢₙₜ and /Qᵢₙₜ are decoupled from Q and /Q.

At the instant t7, the first power switch transistor 317 is closed and operation in a new standby mode ensues. Q, /Q and V_{SSV} start to float to V_{DD} again after /STB=“0”.

1-23 (canceled)

24. A circuit arrangement comprising:
a flip-flop having a plurality of storage transistors with a threshold voltage of a first value;
a first power switch transistor having a threshold voltage of a second value, wherein an application of a predetermined electrical potential to the first power switch transistor's gate terminal brings the circuit arrangement to an operating state in which if at least one supply voltage is switched off, electric charge carriers contained in the circuit arrangement are prevented from discharging from the circuit arrangement; and
a plurality of switching transistors, having a threshold voltage of a third value, provided between the flip-flop and the first power switch transistor, for coupling a flip-flop input signal into the flip-flop;
wherein the magnitude of the first and/or the second value is greater than the magnitude of the third value.

25. The circuit arrangement according to claim 24, wherein the flip-flop has two inverters formed from the storage transistors.

26. The circuit arrangement according to claim 24, wherein the first power switch transistor is a common power switch transistor provided for the flip-flop and for at least one additional flip-flop.

27. The circuit arrangement according to one of claim 24, wherein the thickness of a gate insulating layer of the storage transistors and/or of the first power switch transistor is greater than the thickness of the gate insulating layer of the switching transistors.

28. The circuit arrangement according to claim 24, wherein a channel width of the storage transistors and/or of the first power switch transistor is less than the channel width of the switching transistors.

29. The circuit arrangement according to claim 24, wherein the switching transistors are connected such that, in an operating state of the circuit arrangement in which at least one supply voltage of the circuit arrangement is switched off, each of the terminals of the switching transistors has a defined electrical potential.

30. The circuit arrangement according to claim 24, having at least one second power switch transistor, which is coupled to at least a portion of the switching transistors such that, in an operating state of the circuit arrangement in which at least one supply voltage of the circuit arrangement is switched off, a gate terminal of each of the switching transistors coupled to the at least one second power switch transistor has a defined electrical potential.

31. The circuit arrangement according to claim 24, having at least one third power switch transistor, which is coupled to at least a portion of the switching transistors such that, in an operating state of the circuit arrangement in which at least one supply voltage of the circuit arrangement is switched off, a source/drain terminal of each of the switching transistors coupled to the at least one third power switch transistor has a defined electrical potential.

32. The circuit arrangement according to claim 31, wherein the at least one third power switch transistor is a p-MOS field effect transistor.

33. The circuit arrangement according to claim 24, further comprising a pulse generator circuit that generates a flip-flop input signal from an input signal and from a clock signal and is coupled to the first power switch transistor and to the switching transistors.

34. The circuit arrangement according to claim 33, wherein the pulse generator circuit comprises a plurality of pulse generator transistors having a threshold voltage of a fourth value, wherein the magnitude of the first and/or the second value is greater than the magnitude of the fourth value.

35. The circuit arrangement according to claim 33, wherein the pulse generator circuit comprises a logic subcircuit that generates at least one flip-flop input signal from at least one input signal in accordance with a predetermined logic operation.

36. The circuit arrangement according to claim 35, wherein the logic subcircuit operates as one of an inverter, AND gate, OR gate, NAND gate, NOR gate, exclusive OR gate, and exclusive NOR gate.

37. The circuit arrangement according to claim 36, wherein the logic subcircuit comprises a plurality of logic transistors having a threshold voltage of a fifth value, wherein the magnitude of the first and/or the second value is greater than the magnitude of the fifth value.

38. The circuit arrangement according to claim 24, further comprising a control unit that controls supply voltages applied to terminals of at least a portion of the transistors of the circuit arrangement, wherein the control unit is set such that, in an energy saving operating state, the control unit can switch off all the supply voltages except for supply voltages of the flip-flop.

39. The circuit arrangement according to claim 24, further comprising a test circuit coupled to the flip-flop, wherein the test circuit tests functionality of the flip-flop.

40. The circuit arrangement according to claim 39, wherein the test circuit has an input component that programs a test input signal of the flip-flop, and an output component that reads a test output signal of the flip-flop.

41. The circuit arrangement according to claim 39, wherein the test circuit has a plurality of test transistors with a threshold voltage having a sixth value, wherein the magnitude of the sixth value is greater than at least one of the magnitudes of the third to fifth values.

42. The circuit arrangement according to claim 41, wherein the test transistors have a gate insulating layer having a thickness greater than a thickness of the gate insulating layer of the switching transistors.

43. The circuit arrangement according to claim 34, wherein the test transistors have a gate insulating layer having a thickness greater than a thickness of a gate insulating layer of the pulse generator transistors.

44. The circuit arrangement according to claim 37, wherein the test transistors have a gate insulating layer having a thickness greater than a thickness of a gate insulating layer of the logic transistors.

45. The circuit arrangement according to claim 24, further comprising one or more protection transistors having a threshold voltage of a seventh value and located between the flip-flop and the switching transistors, wherein the protection transistors selectively couple or decouple the flip-flop and the switching transistors, and the magnitude of the seventh value is greater than the magnitude of the third value.

46. The circuit arrangement according to claim 45, wherein the protection transistors have a gate insulating layer having a thickness greater than a thickness of the gate insulating layer of the switching transistors.

47. The circuit arrangement according to claim 34, further comprising one or more protection transistors having a threshold voltage of a seventh value and located between the flip-flop and the switching transistors, wherein the protection transistors selectively couple or decouple the flip-flop and the switching transistors, and the magnitude of the seventh value is greater than the magnitude of the third value, and
wherein the protection transistors have a gate insulating layer having a thickness greater than a thickness of the gate insulating layer of the pulse generator transistors.

48. The circuit arrangement according to claim 37, further comprising one or more protection transistors having a threshold voltage of a seventh value and located between the flip-flop and the switching transistors, wherein the protection transistors selectively couple or decouple the flip-flop and the switching transistors, and the magnitude of the seventh value is greater than the magnitude of the third value, and
wherein the protection transistors have a gate insulating layer having a thickness greater than the thickness of a gate insulating layer of the logic transistors.

49. The circuit arrangement according to claim 45, wherein
in a first operating state, when at least one supply voltage of the circuit arrangement is switched off, by applying electrical control signals to at least a portion of the protection transistors, the protection transistors electrically decouple the flip-flop and the switching transistors from one another; and
in a second operating state, when supply voltages are applied to the circuit arrangement, by applying electrical control signals to at least a portion of the switching transistors, the switching transistors electrically couple the flip-flop and the switching transistors to one another.

50. The circuit arrangement according to claim 45, wherein the protection transistors have at least one transistor pair of transistors of different conduction types connected in parallel with one another, and at least one transistor pair connected by its source/drain terminals between the flip-flop and the switching transistors.
